(19) United States
(12) Patent Application Publication
(10) Pub. No.: US 2025/0267900 A1
(43) Pub. Date: Aug. 21, 2025

(54) SEMICONDUCTOR DEVICE INCLUDING A TRANSISTOR STRUCTURE AND A METHOD OF MANUFACTURING THE SAME

(71) Applicant: SK hynix Inc., Gyeonggi-do (KR)

(72) Inventor: Heon Yong CHANG, Gyeonggi-do (KR)

(21) Appl. No.: 18/800,129

(22) Filed: Aug. 12, 2024

(30) Foreign Application Priority Data
Feb. 16, 2024 (KR) 10-2024-0022412

(51) Int. Cl. H01L 29/10; H01L 21/768; H01L 23/532; H01L 29/08; H01L 29/66

(52) U.S. Cl. CPC H10D 30/751; H01L 21/76897; H01L 23/53266; H10D 62/151; H10D 64/018; H10D 64/021

(57) ABSTRACT

A semiconductor device includes a substrate; a channel layer over the substrate; a gate stack and a gate spacer pattern over the channel layer; an interlayer insulating layer covering the gate stack and the gate spacer pattern; and a contact pattern vertically passing through the interlayer insulating layer to be connected to the substrate. the contact pattern includes a contact plug; and a contact barrier layer surrounding a side surface of the contact plug. The contact barrier layer includes a protrusion portion protruding toward the channel layer in a horizontal direction.

### CROSS-REFERENCE TO RELATED APPLICATIONS

The present application claims priority under 35 U.S.C 119(a) to Korean Patent Application No. 10-2024-0022412, filed on Feb. 16, 2024, which is incorporated herein by reference in its entirety.

### BACKGROUND

### 1. Field

Various embodiments of the present disclosure relate generally to semiconductor technology and, more particularly, to a semiconductor device having a transistor structure and a method of manufacturing the semiconductor device.

### 2. Description of the Related Art

Semiconductor devices having a transistor structure are known. To increase the mobility of the carrier, the transistor structure in which a SiGe layer is used as a channel layer has been proposed.

### SUMMARY

An embodiment of the present disclosure provides a semiconductor device including a transistor structure having a SiGe layer.

An embodiment of the present disclosure provides a method of manufacturing a semiconductor device including a transistor structure having a SiGe layer.

An embodiment of the present disclosure provides a semiconductor device having a contact pattern including a contact barrier layer having a protrusion portion.

An embodiment of the present disclosure provides a method of manufacturing a semiconductor device having a contact pattern including a contact barrier layer having a protrusion portion.

In accordance with an embodiment of the present disclosure, a semiconductor device includes a substrate; a channel layer over the substrate; a gate stack and a gate spacer pattern over the channel layer; an interlayer insulating layer covering the gate stack and the gate spacer pattern; and a contact pattern vertically passing through the interlayer insulating layer to be connected to the substrate. the contact pattern includes a contact plug; and a contact barrier layer surrounding a side surface of the contact plug. The contact barrier layer includes a protrusion portion protruding toward the channel layer in a horizontal direction.

In accordance with another embodiment of the present disclosure, a semiconductor device includes a first transistor structure disposed in a first region; and a second transistor structure disposed in a second region. The first transistor structure includes a channel layer over a substrate; a first gate stack over the channel layer; first gate spacer patterns over both side walls of the first gate stack; first source/drain regions in the substrate adjacent to the first gate spacer patterns, respectively; an interlayer insulating layer covering the first gate stack and the first gate spacer patterns; and first contact patterns vertically passing through the interlayer insulating layer to be connected to the first source/drain regions, respectively. The first contact patterns include first contact plugs and first contact barrier layers surrounding side surfaces of the first contact plugs, respectively. The first contact barrier layers include protrusion portions protruding toward the channel layer in a horizontal direction.

In accordance with another embodiment of the present disclosure, a method of manufacturing a semiconductor device, the method includes forming a channel material layer over a substrate; forming a gate stack over the channel material layer; forming a gate spacer pattern over a side surface of the gate stack; patterning the channel material layer to form a channel layer; forming a source/drain region in the substrate; forming an interlayer insulating layer covering the gate stack and the gate spacer pattern; forming a contact hole vertically penetrating the interlayer insulating layer to expose the source/drain region and a side surface of the channel layer; partially removing the side surface of the channel layer exposed in the contact hole to form a recess region; conformally forming a contact barrier layer on an inner wall of the contact hole, wherein the contact barrier layer fills the recess region; and forming a contact plug over the contact barrier layer to fill the contact hole.

In accordance with another embodiment of the present disclosure, a method of manufacturing a semiconductor device, the method includes forming a channel material layer over a substrate in a first region; forming a first gate stack over the channel material layer; forming first gate spacer patterns on both opposite sidewalls of the first gate stack; forming a channel layer by removing portions of the channel material layer exposed outside of the gate spacer patterns; forming first source/drain regions in the substrate to be adjacent to the first gate spacer patterns; forming an interlayer insulating layer covering the first gate stack and the first gate spacer patterns; forming first contact holes vertically penetrating the interlayer insulating layer to expose the first source/drain regions and side end portions of the channel layer by performing a first etching process; partially removing the side ends of the channel layer exposed in the first contact hole to form recess regions by performing a second etching process; and conformally forming first contact barrier layers to include protrusion portions filling the recess regions over inner sidewalls and bottom surfaces of the first contact holes. The gate spacer patterns vertically overlap with the protrusion portion.

### BRIEF DESCRIPTION OF THE DRAWINGS

FIG. 1A is a longitudinal cross-sectional view illustrating a semiconductor device according to an embodiment of the present disclosure.

FIG. 1B is an enlarged view of the region B of FIG. 1A.

FIGS. 2A to 2P are longitudinal cross-sectional views illustrating a method of manufacturing a semiconductor device according to an embodiment of the present disclosure.

### DETAILED DESCRIPTION

Various embodiments of the present disclosure will be described below in more detail with reference to the accompanying drawings. The present disclosure may, however, be embodied in different forms and should not be construed as limited to the embodiments set forth herein. Rather, these embodiments are provided so that this disclosure will be thorough and complete, and will fully convey the scope of the present disclosure to those skilled in the art. Throughout this disclosure, like reference numerals refer to like parts throughout the various figures and embodiments of the present disclosure.

Hereinafter, the diverse embodiments of the present disclosure will be described in detail with reference to the attached drawings.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

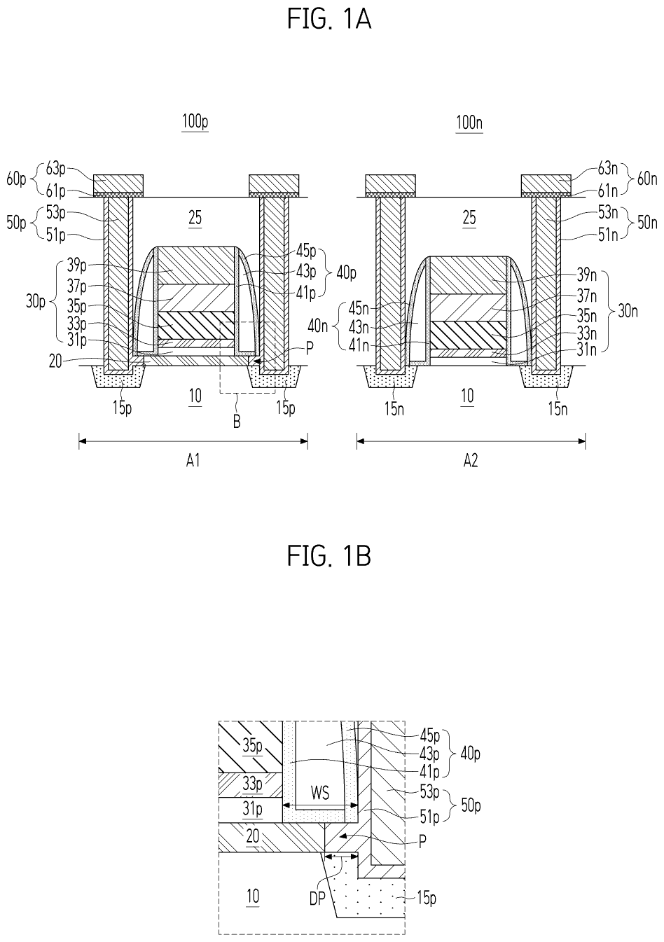

FIG. 1A is a longitudinal cross-sectional view illustrating a semiconductor device according to an embodiment of the present disclosure. Referring to FIG. 1A, a semiconductor device according to an embodiment of the present disclosure may include a first transistor structure 100p disposed in a first region A1. The semiconductor device may further include a second transistor structure 100n disposed in a second region A2. The first region A1 may be a PMOS transistor region, and the second region A2 may be an NMOS transistor region.

Accordingly, the first transistor structure 100p may be a PMOS transistor structure, and the second transistor structure 100n may be an NMOS transistor structure.

The first transistor structure 100p may include a channel layer 20, a first gate stack 30p, first gate spacer patterns 40p, and first contact patterns 50p disposed on the substrate 10. The first transistor structure 100p may further include first source/drain regions 15p disposed in the substrate 10. The first transistor structure 100p may further include first interconnection patterns 60p disposed on the first contact patterns 50p.

The second transistor structure 100n may include a second gate stack 30n, second gate spacer patterns 40n, and second contact patterns 50n disposed on the substrate 10. The second transistor structure 100n may further include second source/drain regions 15n disposed in the substrate 10. The second transistor structure 100n may further include a second interconnection pattern 60n disposed on the second contact patterns 50n. The second gate stack 30n may be directly disposed on the substrate 10 without the channel layer 20.

The semiconductor device may further include an interlayer insulating layer 25 covering and/or surrounding the first and second transistor structures 100p and 100n. The first and second interconnection patterns 60p and 60n may be disposed on the interlayer insulating layer 25.

In the first region A1, the channel layer 20 may be directly formed on an upper surface of the substrate 10. The channel layer 20 may include a silicon germanium (SiGe) layer.

The first gate stack 30p and the first gate spacer patterns 40p may be disposed on or over the channel layer 20. As illustrated, a horizontal width of the channel layer 20 may be greater than a horizontal width of the first gate stack 30p. The horizontal width of the channel layer 20 may be smaller than a total horizontal widths of the first gate stack 30p and the first gate spacers 40p.

The second gate stack 30n and the second gate spacer patterns 40n may be directly disposed on the upper surface of the substrate 10.

The first gate stack 30p may include a first gate insulating layer 31p, a first gate barrier layer 33p, a first lower gate electrode 35p, a first upper gate electrode 37p, and a first gate capping layer 39p stacked in the recited order. The second gate stack 30n may include a second gate insulating layer 31n, a second gate barrier layer 33n, a second lower gate electrode 35n, a second upper gate electrode 37n, and a second gate capping layer 39n.

The first and second gate insulating layer 31p and 31n may include multiple insulating layers, respectively. For example, the first and second gate insulating layer 31p and 31n may each include an interfacial insulating layer, a high-k dielectric layer, and a dipole layer. The interfacial insulating layer may include an oxidized silicon (SiO₂) layer or a silicon nitride (SiN) layer. The high-k dielectric layer may include at least one of a metal oxide layer, a metal inorganic compound layer, or a combination thereof. The metal oxide layer may include at least one of a hafnium oxide (HfO₂) layer, an aluminum oxide layer (Al₂O₃), or a zirconium oxide layer (ZrO₂). The metal inorganic compound may include at least one of a hafnium silicon oxide (HfSiO₂) layer, a hafnium oxide (HfSiO) layer, a hafnium silicon oxide (HfSiO) layer, a hafnium silicon oxide (HfSiON), or an aluminum oxide (AlON) layer, or a combination thereof. The dipole layer may include a lanthanum oxide (La₂O₃) layer.

The first gate barrier layer 33p and the second gate barrier layer 33n may include at least one of a titanium nitride (TiN) layer, a tantalum nitride (TaN) layer, a tungsten nitride (WN) layer, a molybdenum nitride (MoN) layer, or various metal silicide layers such as a titanium silicide (TiSi), a tantalum silicide (TaSi), a tungsten silicide (WSi), a nickel silicide (NiSi), a cobalt silicide (CoSi), or a combination thereof, respectively.

Each of the first lower gate electrode 35p and the second lower gate electrode 35n may include a silicon layer. For example, each of the first lower gate electrode 35p and the second lower gate electrode 35n may include an N-doped polysilicon layer doped with N-type ions such as phosphorous (P), arsenic (As), or antimony (Sb).

Each of the first upper gate electrode 37p and the second upper gate electrode 37n may include a metal such as, for example, tungsten (W), copper (Cu), or molybdenum (Mo).

In an embodiment, a diffusion barrier layer or a metal silicide layer may be further disposed between the first lower gate electrode 35p and the first upper gate electrode 37p, and also between the second lower gate electrode 35n and the second upper gate electrode 37n, respectively. The diffusion barrier layer may include at least one of a titanium nitride (TiN) layer, a tantalum nitride (TaN) layer, a molybdenum nitride (MoN) layer, and a tungsten nitride (WN) layer. The metal silicide layer may include at least one of a tungsten silicide (WSi) layer, a titanium silicide (TiSi) layer, a tantalum silicide (TaSi) layer, a nickel silicide (NiSi) layer, a cobalt silicide (CoSi) layer, or a molybdenum silicide (MoSi) layer.

Each of the first and second gate capping layers 39p and 39n may include a hard mask such as, for example, silicon nitride (SiN) or silicon oxynitride (SiON). For example, each of the first and second gate capping layers 39p and 39n may include an insulating layer.

In an embodiment, the first gate stack 30p may not include at least one of the first gate insulating layer 31p, the first gate barrier layer 33p, the first lower gate electrode 35p, the first upper gate electrode 37p, and the first gate capping layer 39p. In an embodiment, the second gate stack 30n may not include at least one of the second gate insulating layer 31n, the second gate barrier layer 33n, the second lower gate electrode 35n, the second upper gate electrode 37n, and the second gate capping layer 39n.

Sidewalls of the first gate insulating layer 31p, the first gate barrier layer 33p, the first lower and upper gate electrodes 35p and 37p, and the first gate capping layer 39p may be vertically aligned with one another to be vertically coplanar. Sidewalls of the second gate insulating layer 31n, the second gate barrier layer 33n, the second lower and upper gate electrodes 35n and 37n, and the second gate capping layer 39n may be vertically aligned with one another to be vertically coplanar.

The first gate spacer patterns 40p may include first inner gate spacers 41p, first intermediate gate spacers 43p, and first outer gate spacers 45p. The second gate spacer patterns 40n may include second inner gate spacers 41n, second intermediate gate spacers 43n, and second outer gate spacers 45n.

The first and second inner gate spacers 41p and 41n may have an L-shaped cross section, respectively. For example, each of the first inner gate spacers 41p may be disposed on opposite sidewalls of the first gate stack 30p and portions of the upper surface of the channel layer 20. Likewise, the second inner gate spacers 41n may be disposed on both opposite sidewalls of the second gate stack 30n and portions of the upper surface of the substrate 10. Each of the first inner gate spacers 41p and the second inner gate spacers 41n may include silicon nitride (SiN), respectively.

One side surface and a lower surface of each of the first intermediate gate spacers 43p and the second intermediate gate spacers 43n may be in contact with the first inner gate spacers 41p and the second inner gate spacers 41n, respectively. The first intermediate gate spacers 43p and the second intermediate gate spacers 43n may include silicon oxide (SiO₂), respectively.

The first outer gate spacers 45p and the second outer gate spacers 45n may have a curved shape conformally disposed on the outer surfaces of the first intermediate gate spacers 43p and the second intermediate gate spacers 43n, respectively. The first and second outer gate spacers 45p and 45n may include silicon nitride (SiN), respectively. The first outer gate spacers 45p and the second outer gate spacers 45n may be in contact with the first inner gate spacers 41p and the second inner gate spacers 41n, respectively, at uppermost ends and lowermost ends.

The first contact patterns 50p may vertically pass through the interlayer insulating layer 25 to connect the first source/drain regions 15p to the first interconnection patterns 60p. The second contact patterns 50n may vertically pass through the interlayer insulating layer 25 to connect the second source/drain regions 15n to the second interconnection patterns 60n.

The first contact patterns 50p may include first contact barrier layers 51p and first contact plugs 53p, respectively. The second contact patterns 50n may include second contact barrier layers 51n and second contact plugs 53n, respectively. The first contact barrier layers 51p may conformally surround side surfaces and bottom surfaces of the first contact plugs 53p. The second contact barrier layers 51n may conformally surround side surfaces and bottom surfaces of the second contact plugs 53n. For example, each of the first contact barrier layers 51p and the second contact barrier layers 51n may have a tube shape or a cylinder shape. Each of the first contact barrier layers 51p and the second contact barrier layers 51n may include one of a titanium nitride (TIN) layer, a tantalum nitride (TaN) layer, a tungsten nitride (WN) layer, and other metal nitride layers. Each of the first contact plugs 53p and the second contact plugs 53n may have a pillar shape filling the space within the tube or cylinder shape formed by the respective first and second contact barrier layers 51p and 51n. Each of the first contact plugs 53p and the second contact plugs 53n may include a metal such as, for example, tungsten (W).

The first interconnection patterns 60p may include first interconnection barrier layers 61p disposed on the first contact patterns 50p and first interconnection lines 63p disposed on the first interconnection barrier layers 61p. The second interconnection patterns 60n may include second interconnection barrier layers 61n disposed on the second contact patterns 50n and second interconnection lines 63n disposed on the second interconnection barrier layers 61n. The first interconnection barrier layers 61p and the second interconnection barrier layers 61n may include a titanium nitride (TiN) layer. In an embodiment, the first interconnection barrier layers 61p and the second interconnection barrier layers 61n may include a tantalum nitride (TaN) layer or a tungsten nitride (WN) layer. The first interconnection lines 63p and the second interconnection lines 63n may include a metal such as, for example, tungsten (W). In an embodiment, the first i interconnection barrier layers 61p and the second interconnection barrier layers 61n may further include metal silicide layers disposed on the first contact patterns 50p and the second contact patterns 50n, respectively. The metal silicide layers may include one of cobalt silicide (CoSi), titanium silicide (TiSi), tungsten silicide (WSi), tantalum silicide (TaSi), nickel silicide (NiSi), or other metal silicides.

FIG. 1B is an enlarged view of the region B of FIG. 1A. Referring to FIG. 1B, the channel layer 20 may be recessed in a horizontal direction between the first gate spacer pattern 40p and the substrate 10, or, in particular, between the first gate spacer pattern 40p and the first source/drain regions 15p.

The first contact barrier layer 51p of the first contact pattern 50p may protrude toward the channel layer 20. That is, the first contact barrier layer 51p may have a protrusion portion P protruding to the channel layer 20. The protrusion portion P may also be referred to as a horizontal extension of the first contact barrier layer 51p.

In the horizontal direction, a side end portion of the channel layer 20 may be located in a middle of the first gate spacer pattern 40p. Accordingly, a recessed horizontal depth DP of the channel layer 20 or a horizontal length DP of the protrusion portion P may be smaller than a horizontal width WS of the first gate spacer pattern 40p. The first source/drain regions 15p may extend and expand to a lower portion of the recessed side end portion of the channel layer 20. The first source/drain regions 15p may be in contact with the lower surface of the protrusion P.

The protrusion portion P and the channel layer 20 may be located at the same horizontal level. More specifically, an upper surface (a top surface) of the channel layer 20 and an upper surface of the protrusion portion P may be coplanar, and a lower surface (a bottom surface) of the channel layer 20 and a lower surface of the protrusion portion P may be coplanar. The protrusion portion P may be directly in contact with a side end of the channel layer 20. The first gate spacer pattern 40p may vertically overlap the protrusion portion P.

The protrusion portion P of the first contact barrier layer 51p of the first contact pattern 50p is advantageous because it may prevent metal atoms (e.g., tungsten (W) atoms) diffusing or penetrating from the first contact plug 53p into the channel layer 20.

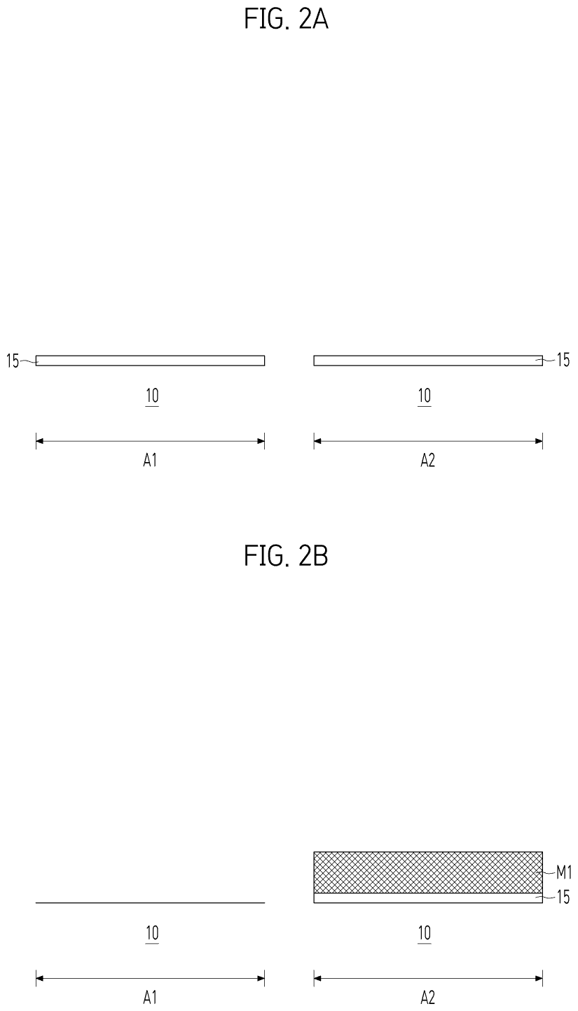

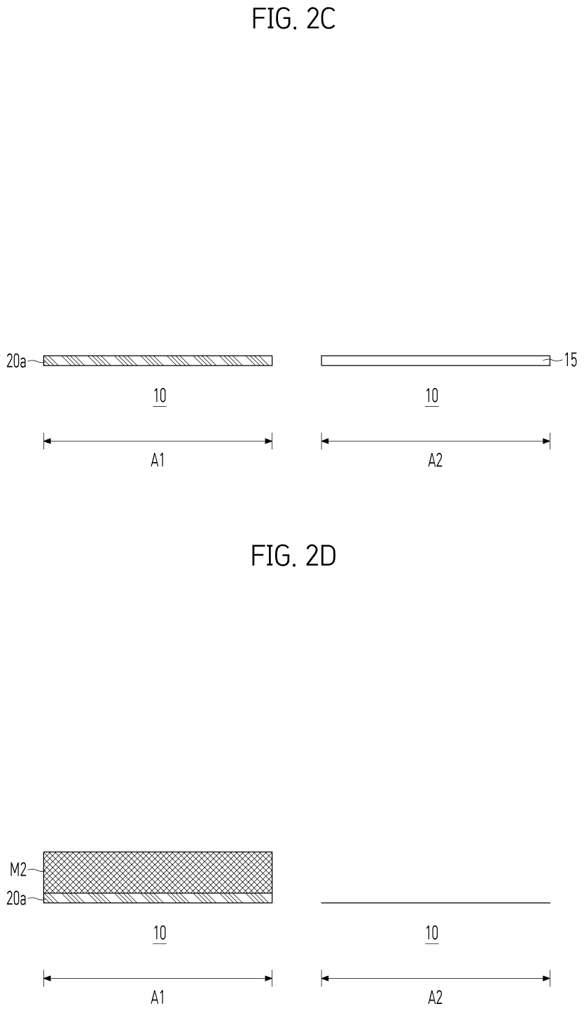

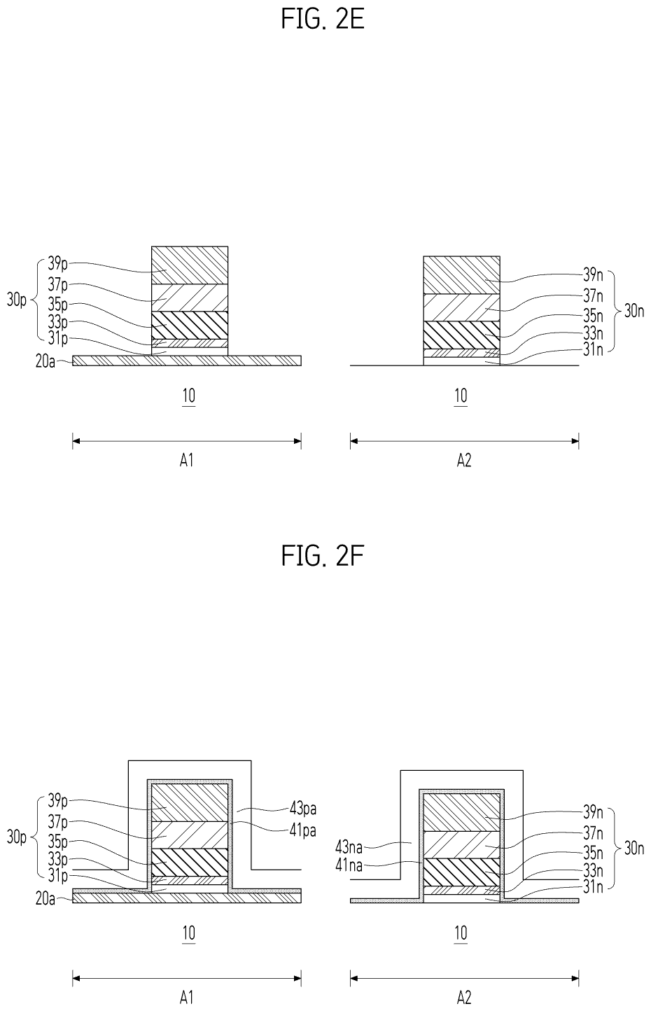

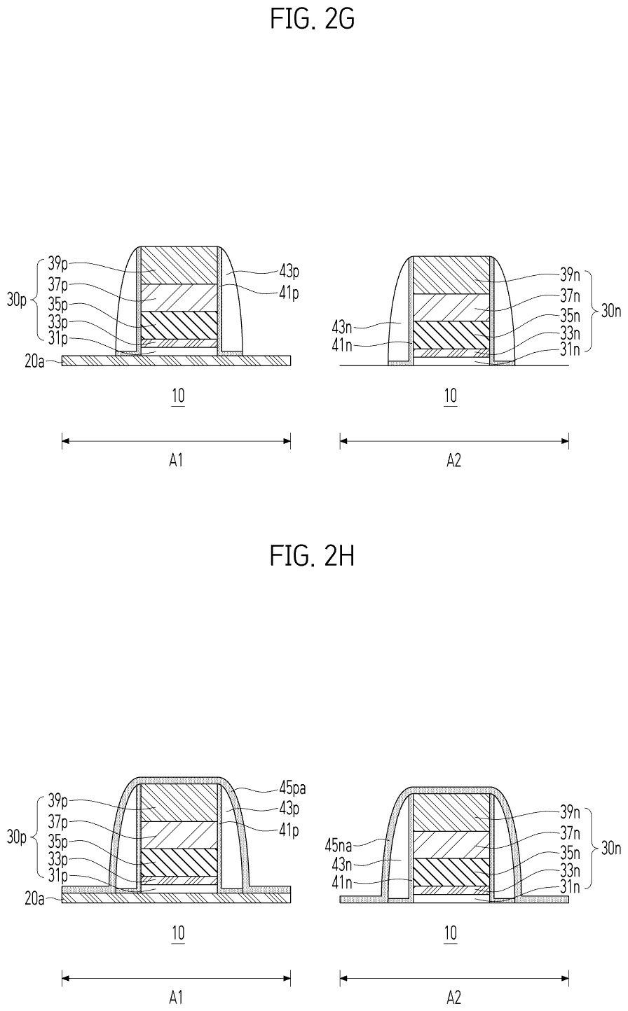

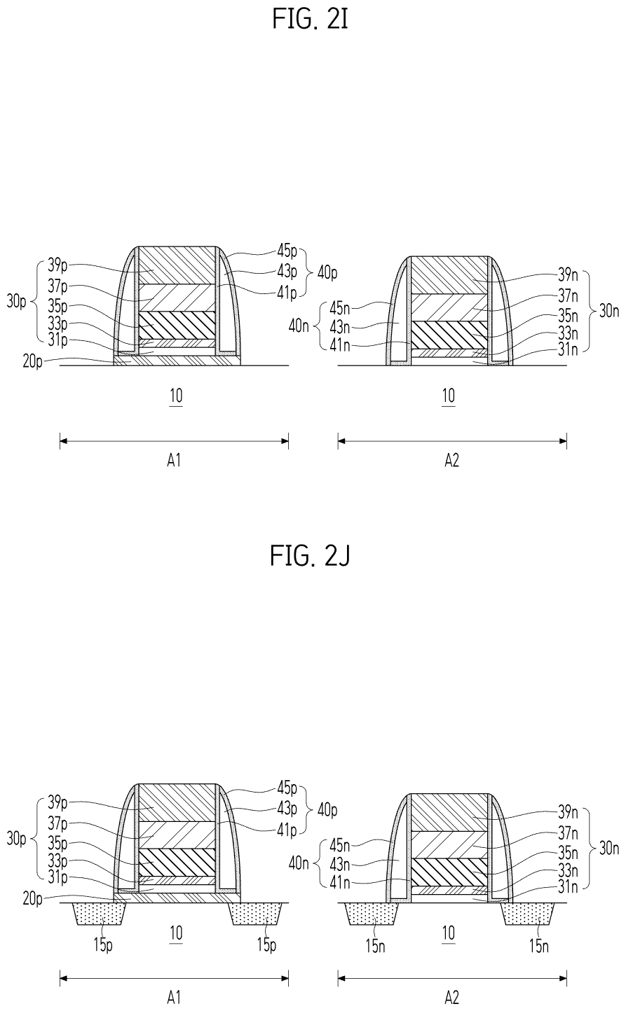

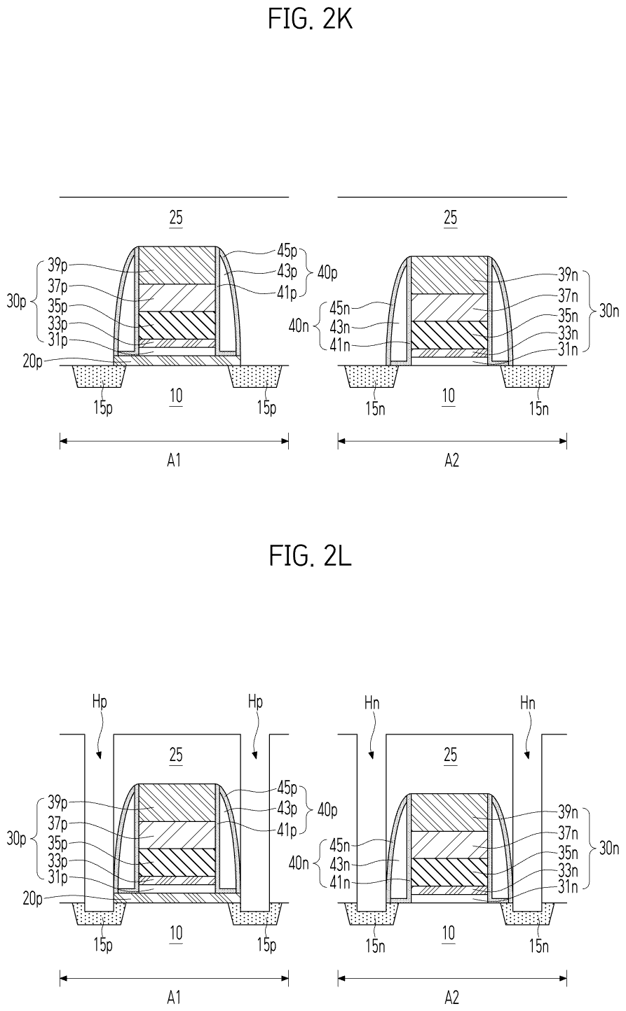

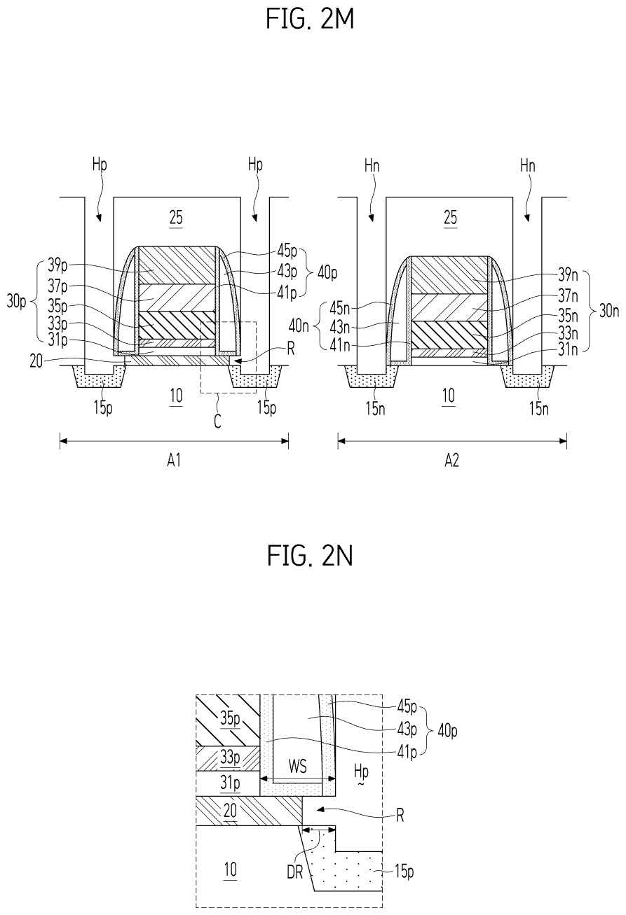

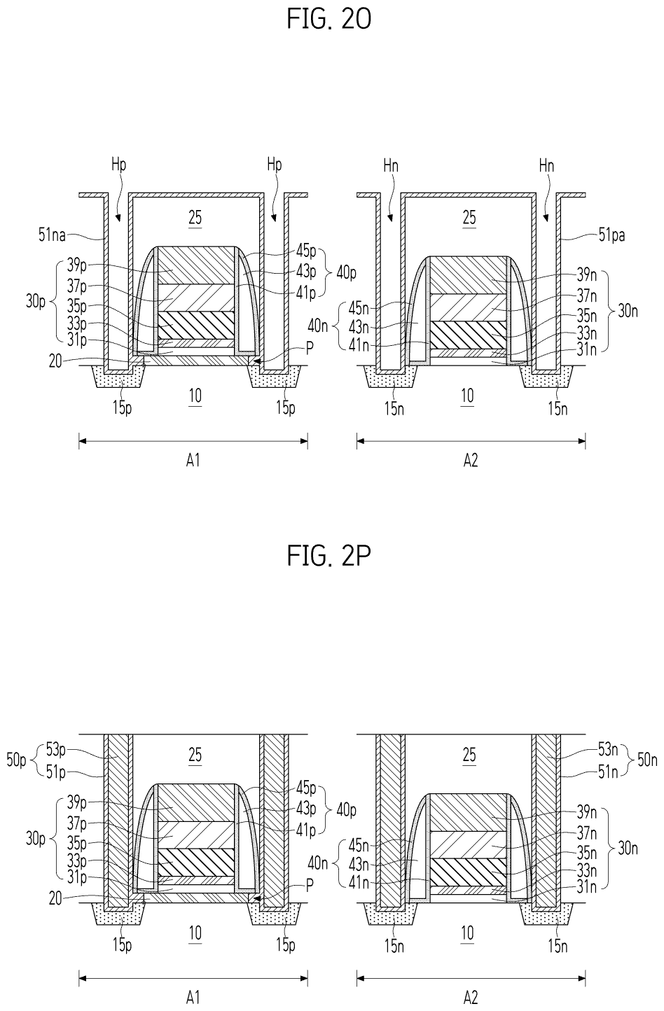

FIGS. 2A to 2P are longitudinal cross-sectional views illustrating a method of manufacturing a semiconductor device according to an embodiment of the present disclosure. Referring now to FIG. 2A, a method of manufacturing a semiconductor device, according to an embodiment of the present disclosure, may include forming a buffer oxide layer 15 in common over a first region A1 and a second region A2 of a substrate 10. The first region A1 may include a PMOS transistor region. The second region A2 may include an NMOS transistor region.

The substrate 10 may include a semiconductor material layer. Any suitable semiconductor material may be used. For example, the substrate 10 may include one of a silicon wafer, an epitaxial growth layer such as silicon germanium (SiGe) or silicon carbide (SIC), or a silicon layer including at least one of aluminum (Al), gallium (Ga), arsenic (As), phosphorus (P), boron (B), antimony (Sb), or other impurities.

The buffer oxide layer 15 may be commonly formed in the first region A1 and the second region A2. Forming the buffer oxide layer 15 may include performing an oxidation process to oxidize a surface of the substrate 10 to form an oxidized silicon layer. In an embodiment, forming the buffer oxide layer 15 may include forming a silicon oxide layer over the surface of the substrate 10 by performing a deposition process such as chemical vapor deposition (CVD).

Referring to FIG. 2B, the method may further include removing the buffer oxide layer 15 in the first region A1. For example, the method may include forming a first mask pattern M1 that exposes the first region A1 and covers the second region A2. Then the process may include removing the oxide layer 15 over the substrate 10 in the first region A1 via, for example, by an etching process or another suitable removing process using the first mask pattern M1 as an etching mask to protect the oxide over the second region A2. Thus, the surface of the substrate 10 may be exposed in the first region A1.

The first mask pattern M1 may include any suitable photoresist. Thereafter, the method may further include removing the first mask pattern M1.

Referring to FIG. 2C, the method may further include forming a channel material layer 20a over the exposed substrate 10 in the first region A1. Forming the channel material layer 20a may include forming a silicon germanium (SiGe) layer over the substrate 10 by performing an epitaxial growth process.

Referring to FIG. 2D, the method may further include removing the buffer oxide layer 15 in the second region A2. For example, the method may further include forming a second mask pattern M2 that covers the first region A1 and exposes the second region A2, and performing an etching process or a removal process using the second mask pattern M2 as an etching mask to remove the buffer oxide layer 15 only over the substrate 10 in the second region A2. The surface of the substrate 10 may be exposed in the second area A2.

The second mask pattern M2 may include any suitable photoresist. Thereafter, the method may further include removing the second mask pattern M2.

Referring to FIG. 2E, the method may further include forming first and second gate stacks 30p and 30n over the first and second regions A1 and A2, respectively. The first gate stack 30p may be formed over the channel material layer 20a in the first region A1 and the second gate stack 30n may be formed over the substrate 10 in the second region A2. For example, the first gate stack 30p may include a PMOS gate stack, and the second gate stack 30n may include an NMOS gate stack.

The first gate stack 30p may include a first gate insulating layer 31p, a first gate barrier layer 33p, a first lower gate electrode 35p, a first upper gate electrode 37p, and a first gate capping layer 39p. The second gate stack 30n may include a second gate insulating layer 31n, a second gate barrier layer 33n, a second lower gate electrode 35n, a second upper gate electrode 37n, and a second gate capping layer 39n.

Forming the gate stacks 30p and 30n may include forming a gate insulating material layer, a gate barrier material layer, a lower gate electrode material layer, an upper gate electrode material layer, and a gate capping material layer, and performing a photolithography process and a patterning process (i.e., an etching process).

Forming the gate insulating material layer may include forming multiple insulating layers. For example, the gate insulating material layer may include an interfacial insulating material layer, a high-k dielectric material layer, and a dipole material layer. The interfacial insulating material layer may include a channel material layer 20a or an oxidized silicon (SiO2) layer obtained by oxidizing a surface of the substrate 10. In an embodiment, the interfacial insulating material layer may include a deposited silicon oxide (SiO2) layer. The high-k dielectric material layer may include a metal such as hafnium. For example, the high-k dielectric layer may include a hafnium oxide (HfO2) layer or a hafnium silicon oxide (HfSiO2) layer. The dipole material layer may include lanthanum (La). For example, the dipole material layer may include a lanthanum oxide (La2O3) layer. Accordingly, the first gate insulating layer 31p and the second gate insulating layer 31n may have a stacked structure of an interfacial insulating layer, a high-k dielectric layer, and a dipole layer.

Forming the gate barrier material layer may include forming a titanium nitride (TiN) layer, a tantalum nitride (TaN) layer, or a tungsten nitride (WN) layer. Accordingly, the first gate barrier layer 33p and the second gate barrier layer 33n may include at least one of a titanium nitride (TiN) layer, a tantalum nitride (TaN) layer, and a tungsten nitride (WN) layer.

Forming the lower gate electrode material layer may include forming a doped polysilicon layer. Accordingly, the first lower gate electrode 35p and the second lower gate electrode 35n may include an N-doped polysilicon layer doped with N-type ions.

Forming the upper gate electrode material layer may include forming a metal layer such as, for example, tungsten (W). Accordingly, each of the first upper gate electrode 37p and the second upper gate electrode 37n may include a metal such as, for example, tungsten (W).

In an embodiment, a diffusion barrier material layer or a metal silicide layer (not shown) may be further formed between the lower gate electrode material layer and the upper gate electrode material layer. The diffusion barrier layer may include at least one of a titanium nitride (TiN) layer, a tantalum nitride (TaN) layer, and a tungsten nitride (WN) layer. The metal silicide layer may include at least one of a tungsten silicide (WSi) layer, a titanium silicide (TiSi) layer, a tantalum silicide (TaSi) layer, a nickel silicide (NiSi) layer, or a cobalt silicide (CoSi) layer.

Forming the gate capping material layer may include forming a hard mask such as, for example, silicon nitride (SiN) or silicon oxynitride (SiON) over the upper gate electrode material layer. Accordingly, each of the first and second gate capping layers 39p and 39n may include a hard mask such as, for example, silicon nitride (SiN) or silicon oxynitride (SiON). For example, the first and second gate capping layers 39p and 39n may each include an insulating layer. In the first area A1, a surface of the channel material layer 20a may be exposed, while in the second area A2, the surface of the substrate 10 may be exposed.

Referring to FIG. 2F, the method may further include forming first and second inner gate spacer material layers 41pa and 41na and first and second intermediate gate spacer material layers 43pa and 43na. Forming the first and second inner gate spacer material layers 41pa and 41na and forming the first and second intermediate gate spacer material layers 43pa and 43na may include performing a deposition process such as CVD, respectively. The first inner gate spacer material layers 41pa may be conformally formed on both opposite sidewalls and an upper surface of the first gate stack 30p, and the exposed surface of the channel material layer 20a. The second inner gate spacer material layers 41na may be conformally formed on both opposite sidewalls and an upper surface of the second gate stack 30n, and the exposed surface of the substrate 10.

The first and second intermediate gate spacer material layers 43pa and 43na may be conformally formed on the first and second inner gate spacer material layers 41pa and 41na, respectively. The first and second inner gate spacer material layers 41pa and 41na may include a silicon nitride (SiN) layer. The first and second intermediate gate spacer material layers 43pa and 43na may include a silicon oxide (SiO2) layer.

Referring to FIG. 2G, the method may further include forming first and second inner gate spacers 41p and 41n and first and second intermediate gate spacers 43p and 43n on both opposite sidewalls of the first and second gate stacks 30p and 30n by performing a first etch-back process. Upper surfaces of the first and second gate capping layers 39p and 39n may be exposed. The upper surface of the channel material layer 20a may be exposed in the first area A1. The upper surface of the substrate 10 may be exposed in the second area A2. The first inner gate spacers 41p may be conformally formed in an L-shape on both opposite side surfaces of the first gate stack 30p and the exposed upper surface of the channel material layer 20a. The second inner gate spacers 41n may be conformally formed in an L-shape on both opposite side surfaces of the second gate stack 30n and the exposed upper surface of the substrate 10. That is, in the first region A1, the first inner gate spacers 41p may be formed over a portion of the surface of the channel material layer 20a adjacent to the first gate stack 30p. In the second region A2, the second inner gate spacers 41n may be formed on a portion of the surface of the substrate 10 adjacent to the second gate stack 30n. The first and second intermediate gate spacers 43p and 43n may be formed on outer surfaces and upper surfaces of the first and second inner gate spacers 41p and 41n, respectively. In the first region A1, the first intermediate gate spacers 43p may be formed on the first inner gate spacers 41p formed on a portion of the channel material layer 20a. In the second region A2, the second intermediate gate spacers 43n may be formed on the second inner gate spacers 41n formed on a portion of the substrate 10.

Referring to FIG. 2H, the method may further include forming first and second outer gate spacer material layers 45pa and 45na, for example, via a deposition process such as a CVD. The first and second outer gate spacer material layers 45pa and 45na may be conformally formed on the upper surfaces of exposed first and second gate capping layers 39p and 39n of the first and second gate stacks 30p and 30n, surfaces of the first and second intermediate gate spacers 43pa and 43na, the upper surface of the channel material layer 20a exposed in the first region A1, and the upper surface of the substrate 10 exposed in the second region A2, respectively. The first and second outer gate spacer material layers 45pa and 45na may include a silicon nitride (SiN) layer.

Referring to FIG. 2I, the method may further include performing a second etch-back process to form first and second external gate spacers 45p and 45n. The first and second outer gate spacers 45p and 45n may be formed over the first and second intermediate gate spacers 43p and 43n, respectively. First gate spacer patterns 40p including first inner gate spacers 41p, first intermediate gate spacers 43p, and first outer gate spacers 45p may be formed. Second gate spacer patterns 40n including second inner gate spacers 41n, second intermediate gate spacers 43n, and second outer gate spacers 45n may be formed.

In the first area A1, portions of the channel material layer 20a exposed outside of the gate spacer pattern 40n may be removed so that the surface of the substrate 10 may be exposed. The channel material layer 20a may remain under the first gate stack 30p and the first and second spacer patterns 40p and 40n to be formed as a preliminary channel layer 20p. In the first region A1, first gate spacer patterns 40p including first inner gate spacers 41p, first intermediate gate spacers 43p, and first outer gate spacers 45p may be formed. In the second region A2, second gate spacer patterns 40n may be formed to include second inner gate spacers 41n, second intermediate gate spacers 43n, and second outer gate spacers 45n. In the first region A1, outer surfaces of the first outer gate spacers 45p and both side cross-sections of the preliminary channel layer 20p may be vertically aligned.

Referring to FIG. 2J, the method may further include forming first source/drain regions 15p and second source/drain regions 15n by performing an ion implantation process. The first source/drain regions 15p may be formed in the substrate 10 in regions which are adjacent to side surfaces of the first gate spacer patterns 40p and both side ends of the preliminary channel layer 20p in the first region A1. The second source/drain regions 15n may be formed in the substrate 10 adjacent to side surfaces of the second gate spacer patterns 40n in the second region A2. The first source/drain regions 15p may include boron (B). The second source/drain regions 15n may include arsenic (As) and/or phosphorus (P). The first and second outer gate spacer material layers 45pa and 45na may be thinned to be formed as first and second outer gate spacer layers 45p and 45n.

The first source/drain regions 15p may be formed by performing a first ion doping process after forming a first mask pattern (for example, refer to the first mask pattern M1 of FIG. 2B) that exposes the first region A1 and covers the second region A2. The second source/drain regions 15n may be formed by performing a second ion doping process after forming a mask pattern (for example, refer to the second mask pattern M2 of FIG. 2D) covering the first region A1 and exposing the second region A2. The first source/drain regions 15p may horizontally extend and expand to lower portions of the first gate spacer patterns 40p and lower portions of the preliminary channel layer 20p. The second source/drain regions 15n may horizontally extend and expand to lower portions of the second gate spacer patterns 40n.

Referring to FIG. 2K, the method may further include forming an interlayer insulating layer 25 as a whole in the first region A1 and the second region A2. The interlayer insulating layer 25 may include a silicon oxide (SiO2) layer. The method may further include planarizing an upper surface of the interlayer insulating layer 25 by performing a planarization process such as CMP.

Referring to FIG. 2L, the method may further include forming the first and second contact holes Hp and Hn by performing a first etching process. The first and second contact holes Hp and Hn may vertically penetrate the interlayer insulating layer 25 to expose the first source/drain regions 15p and the second source/drain regions 15n, respectively. The lowermost surfaces of the first and second contact holes Hp and Hn may be positioned lower than the top surface of the substrate 10. For example, surfaces of the first source/drain regions 15p and the second source/drain regions 15n exposed in the first and second contact holes Hp and Hn may be recessed.

Referring to FIG. 2M, the method may further include performing a second etching process to form recess regions R in the first contact holes Hp in the first region A1. The recess regions R may be formed by partially removing both ends of the preliminary channel layer 20p. The second etching process may include selectively removing the preliminary channel layer 20p, for example, silicon germanium (SiGe). Both side ends of the preliminary channel layer 20p may be partially removed to be formed into the channel layer 20.

FIG. 2N is an enlarged view of the ‘C’ area of FIG. 2M. Referring to FIG. 2N, the recess region R may be formed under a portion of the first gate space pattern 40p. A horizontal width WS of the first gate spacer pattern 40p may be greater than a horizontal depth DR of the recess region R. The side end portion of the channel layer 20 may be horizontally located in a middle of the first gate spacer pattern 40p. Side end portions of the first source/drain regions 15p may be located under the channel layer 20.

Referring to FIG. 2O, the method may further include conformally forming first and second contact barrier material layers 51pa and 51na on inner walls and bottom surfaces of the first and second contact holes Hp and Hn. In the first region A1, the first contact barrier material layer 51pa may fill the recess region R. That is, the first contact barrier material layer 51pa may form a protrusion portion P. Forming the first and second contact barrier material layers 51pa and 51na may include performing a deposition process such as CVD. The first and second contact barrier material layers 51pa and 51na may include, for example, a titanium nitride (TiN) layer. In an embodiment, the first and second contact barrier material layers 51pa and 51na may include a tantalum nitride (TaN) layer or a tungsten nitride (WN) layer. Referring to FIG. 2P, the method may further include forming first and second contact plugs 53p and 53n filling the first and second contact holes Hp and Hn to form first and second contact patterns 50p and 50n. The method may further include performing a planarization process such as a CMP to coplanarize upper surfaces of the first and second contact patterns 50p and 50n and an upper surface of the interlayer insulating layer 25.

Thereafter, referring to FIG. 1A, the method may further include forming the first and second interconnection patterns 60p and 60n. Forming the first and second interconnection patterns 60p and 60n may include performing a deposition process, a photolithography process, and a patterning process to form first and second interconnection barrier layers 61p and 61n and first and second interconnection lines 63 on upper surfaces of the interlayer insulating layer 25. Forming the first and second interconnection barrier layers 61p and 61n may include forming a titanium nitride (TiN) layer by performing a deposition process. In an embodiment, forming the first and second interconnection barrier layers 61p and 61n may include forming a tantalum nitride (TaN) layer or a tungsten nitride (WN) layer by performing a deposition process. Forming the first and second interconnection lines 63p and 63n may include forming a metal layer such as a tungsten (W) layer by performing a deposition process. In an embodiment, forming the first and second interconnection barrier layers 61p and 61n may further include forming metal silicide layers on the interlayer insulating layer 25 by performing a deposition process. The metal silicide layers may include at least one of cobalt silicide (CoSi), titanium silicide (TiSi), tungsten silicide (WSi), tantalum silicide (TaSi), nickel silicide (NiSi), or other metal silicides.

According to embodiments of the present disclosure, a gap between the SiGe channel layer and the metal contact plug can be sufficiently provided, so that leakage current can be reduced.

While the present disclosure has been described with respect to the specific embodiments, it will be apparent to those skilled in the art that various changes and modifications may be made without departing from the spirit and scope of the disclosure as defined in the following claims. Furthermore, the embodiments may be combined to form additional embodiments.

What is claimed is:

1. A semiconductor device comprising:
a channel layer disposed over a substrate;
a gate stack and a gate spacer pattern disposed over the channel layer;
an interlayer insulating layer covering the gate stack and the gate spacer pattern; and
a contact pattern vertically passing through the interlayer insulating layer to be connected to the substrate,
wherein the contact pattern includes:
a contact plug; and
a contact barrier layer surrounding a side surface of the contact plug,
wherein the contact barrier layer includes a protrusion portion extending in a horizontal direction toward the channel layer.

2. The semiconductor device of claim 1,
wherein a side end portion of the channel layer is recessed from an outer surface of the gate spacer pattern in the horizontal direction.

3. The semiconductor device of claim 1,
wherein a side end portion of the channel layer is in contact with the protrusion portion of the contact barrier layer.

4. The semiconductor device of claim 1,
wherein a gate spacer pattern vertically overlaps with the protrusion portion.

5. The semiconductor device of claim 1,
wherein a horizontal width of the channel layer is greater than a horizontal width of the gate stack.

6. The semiconductor device of claim 1,
wherein the gate stack includes:
a gate insulating layer;
a gate barrier layer;
a gate electrode layer; and
a gate capping layer,
wherein sidewalls of the gate insulating layer, the gate barrier layer, the gate electrode layer, and the gate capping layer are vertically coplanar.

7. The semiconductor device of claim 6,
wherein the gate insulating layer includes an interfacial insulating layer, a high-k dielectric layer, and a dipole layer vertically stacked.

8. The semiconductor device of claim 1,
wherein the gate spacer pattern includes:
an inner gate spacer including silicon nitride;
an intermediate gate spacer including silicon oxide; and
an outer gate spacer layer including silicon nitride,
wherein the internal gate spacer is conformally disposed on a sidewall of the gate stack and a portion of an upper surface of the channel layer to have an L-shape,
wherein the intermediate gate spacer is disposed over the inner gate spacer, and
wherein the outer gate spacer is conformally disposed over an outer surface of the intermediate gate spacer.

9. The semiconductor device of claim 1,
wherein the channel layer includes a silicon germanium layer disposed over the substrate.

10. The semiconductor device of claim 1,
wherein the contact barrier layer includes a metal nitride layer, and
wherein the contact plug includes a metal.

11. A semiconductor device comprising:
a first transistor structure disposed in a first region; and
a second transistor structure disposed in a second region,
wherein the first transistor structure includes:
a channel layer over a substrate;
a first gate stack over the channel layer;
first gate spacer patterns over both side walls of the first gate stack;
first source/drain regions in the substrate to be adjacent to the first gate spacer patterns, respectively;
an interlayer insulating layer covering the first gate stack and the first gate spacer patterns; and
first contact patterns vertically passing through the interlayer insulating layer to be connected to the first source/drain regions, respectively,
wherein the first contact patterns include first contact plugs and first contact barrier layers surrounding side surfaces of the first contact plugs, respectively,
wherein the first contact barrier layers include protrusion portions protruding toward the channel layer in a horizontal direction.

12. The semiconductor device of claim 11,
wherein a horizontal width of the channel layer is greater than a horizontal width of the first gate stack.

13. The semiconductor device of claim 11,
wherein a horizontal width of the channel layer is less than a sum of a horizontal width of the first gate stack and horizontal widths of the first gate spacer patterns.

14. The semiconductor device of claim 11,
wherein the protrusion portions vertically overlap with the first gate spacer patterns, respectively.

15. The semiconductor device of claim 11,
wherein the channel layer and the protrusion portions of the first contact barrier layers are in direct contact with each other.

16. The semiconductor device of claim 11,
wherein the second transistor structure includes:
a second gate stack directly disposed over the substrate;
second gate spacer patterns disposed on both opposite sidewalls of the second gate stack;
second source/drain regions in the substrate to be adjacent to the second gate spacer patterns, respectively; and
second contact patterns vertically passing through the interlayer insulating layer and connected to the second source/drain regions, respectively,
wherein the second contact patterns include second contact plugs and second contact barrier layers surrounding side surfaces of the second contact plugs, respectively.
